(19) United States
(12) Patent Application Publication
(10) Pub. No.: US 2026/0314248 A1
(43) Pub. Date: Oct. 8, 2026

(54) TANDEM PEROVSKITE SOLAR CELL AND MANUFACTURING METHOD THEREOF

(71) Applicant: HANWHA SOLUTIONS CORPORATION, Seoul (KR)

(72) Inventors: Sang Soo KIM, Seoul (KR); Kyeong Il HWANG, Seoul (KR); Chang Min IN, Seoul (KR)

(73) Assignee: HANWHA SOLUTIONS CORPORATION, Seoul (KR)

(21) Appl. No.: 19/637,344

(22) Filed: Apr. 2, 2026

(30) Foreign Application Priority Data
Apr. 2, 2025 (KR) 10-2025-0042860
Sep. 3, 2025 (KR) 10-2025-0124561

(51) Int. Cl. H10K 71/60; H10F 10/161; H10K 30/10; H10K 30/57; H10K 30/82; H10K 85/50

(52) U.S. Cl. CPC H10K 71/60; H10F 10/161; H10K 30/10; H10K 30/57; H10K 30/82; H10K 85/50

(57) ABSTRACT

The present invention relates to a tandem perovskite solar cell in which a laser edge isolation process is introduced in a process of manufacturing a solar cell, and a manufacturing method thereof.

### CROSS-REFERENCE TO RELATED APPLICATIONS

The present application claims priority under 35 U.S.C. § 119(a) to Korean Patent Application Number 10-2025-0042860, filed on Apr. 2, 2025, and Korean Patent Application Number 10-2025-0124561, filed on Sep. 3, 2025, in the Korean Intellectual Property Office, the entire disclosures of which are incorporated herein by reference.

### TECHNICAL FIELD

The present invention relates to a tandem perovskite solar cell in which a laser edge isolation process is introduced in a process of manufacturing a solar cell, and a manufacturing method thereof.

### BACKGROUND OF THE INVENTION

In order to solve the problem of depletion of fossil energy and environmental problems caused by its use, research on renewable and clean alternative energy sources such as solar energy, wind power, and hydropower is actively being conducted. Among them, interest in a solar cell that directly converts electrical energy from sunlight has greatly increased. Herein, the solar cell refers to a cell which generates current-voltage using a photovoltaic effect for generating electrons and holes by absorbing light energy from sunlight.

Currently, a silicon (Si) single crystal based solar cell of an n-p diode type having a light energy conversion efficiency exceeding 20% is available and used in actual solar power generation, and there are also solar cells using compound semiconductors such as gallium arsenide (GaAs) which have higher conversion efficiencies. However, these inorganic semiconductor based solar cells require highly purified materials for high efficiency, consuming a lot of energy in refining raw materials, and also require expensive process equipment for single crystal or thin film formation, limiting the reduction of manufacturing costs for the solar cells and hindering large-scale commercialization.

Accordingly, in order to manufacture a solar cell at low cost, it is necessary to significantly reduce the costs of materials or manufacturing processes used as key components for the solar cell, and research on perovskite solar cells that can be manufactured with low-cost materials and processes as an alternative to inorganic semiconductor based solar cells is being conducted.

The general structure having a perovskite structure is an ABX₃ structure in which anions are located at the X site, large cations are located at the A site, and small cations are located at the B site.

Unlike crystalline materials, perovskite compounds which are polyanionic solids contain ionic defects, and when a device made of perovskites is exposed to external environments (heat/light/bias/stress/moisture etc.), these defects act as factors that degrade the performance of the devices, leading to issues in defining steady state conditions and accurate measurement of performance parameters not only for stability but also for normal operation of perovskite solar cells.

Meanwhile, a perovskite solar cell capable of absorbing light in the short wavelength region may be stacked on the crystalline silicon solar cell to manufacture tandem perovskite solar cells. Specifically, as shown in FIG. 1, in manufacturing a tandem solar cell including a stack in which a lower cell 1, a recombination layer 10, a hole transport layer 20, a perovskite light absorbing layer 30, an intermediate layer 40, an electron transport layer 50, and a transparent electrode 60 are sequentially stacked, a bottom-up method is mainly used, but this method has disadvantages in that mass production is insufficient and non-deposition area occurs and the deposition time is long due to the use of a tray. To solve these problems, a top-down method should be introduced for high speed and full surface deposition. However, when the transparent electrode 60 is deposited on the electron transport layer 50 using the top-down method, since it is difficult to deposit only on the upper surface of the electron transport layer 50, the transparent electrode is deposited without directionality and also on the side surfaces of the tandem perovskite solar cell, thereby forming a shunt path, which prevents it from performing a charge selective role, accelerates charge recombination, and ultimately causes heat generation in the tandem perovskite solar cell.

### PRIOR ART

### Patent Literature

Korean Patent Registration No 10-2019310 (Publication date Mar. 30, 2015)

### SUMMARY

### Technical Problem

The present invention has been made in an effort to solve the above problems, and provides a tandem perovskite solar cell and a manufacturing method thereof, which can manufacture a perovskite solar cell having excellent performance by introducing a laser edge isolation process after deposition of a transparent electrode in a process for manufacturing a perovskite solar cell so as to cut off a shunt path and allow charges to move toward a charge selective layer.

### Solution to Problem

In order to solve the above problems, a manufacturing method of a perovskite solar cell of the present invention may include: a first step of preparing a stack in which a hole transport layer, a perovskite light absorbing layer and an electron transport layer are sequentially stacked; a second step of forming a transparent electrode on the electron transport layer; a third step of cutting both ends of the transparent electrode in a vertical direction to one surface of the transparent electrode through a laser edge isolation process; and a fourth step of forming a metal electrode on the transparent electrode.

In a preferred embodiment of the present invention, the stack may further include an intermediate layer between the perovskite light absorbing layer and the electron transport layer.

In a preferred embodiment of the present invention, the laser edge isolation process may be performed using a pulsed laser under conditions of a laser wavelength of 300 to 400 nm and a pulse duration of 5 to 15 Ps.

In a preferred embodiment of the present invention, the laser edge isolation process may be performed under conditions of a power of 0.1 to 1.0 W, a scan speed of 500 to 1,500 mm/s, a repetition rate of 300 to 700 kHz, a scanner z-axis of 5.0 to 15.0 mm, and a spot distance of 0.5 to 5 μm.

In a preferred embodiment of the present invention, the transparent electrode may be a transparent thin film formed by depositing indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO).

In a preferred embodiment of the present invention, the perovskite light absorbing layer may include a perovskite material represented by Chemical Formula 1 below.

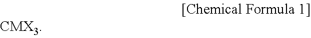

In Chemical Formula 1, C is a monovalent cation, M is a divalent cation, and X is a monovalent anion.

Meanwhile, the manufacturing method of a tandem perovskite solar cell of the present invention may include: a first step of preparing a stack in which a lower cell, a recombination layer, a hole transport layer, a perovskite light absorbing layer and an electron transport layer are sequentially stacked; a second step of forming a transparent electrode on the electron transport layer; a third step of cutting both ends of the transparent electrode in a vertical direction to one surface of the transparent electrode through a laser edge isolation process; and a fourth step of forming a metal electrode on the transparent electrode.

In a preferred embodiment of the present invention, the recombination layer, the hole transport layer, the perovskite light absorbing layer and the electron transport layer of the third step may be cut by using a laser edge isolation process, and the lower cell may not cut.

In a preferred embodiment of the present invention, the lower cell in the first step may be a polycrystalline silicon solar cell, a crystalline silicon solar cell, a perovskite solar cell, a gallium arsenide (GaAs) solar cell, a cadmium telluride (CdTe) solar cell, a CuInGaSe (CIGS) solar cell, a Cu2ZnSnS4 (CZTS) solar cell, an organic solar cell, a dye-sensitized solar cell, or a group III-V compound solar cell.

In addition, the tandem perovskite solar cell of the present invention is sequentially stacked with a lower cell, a recombination layer and an upper cell, wherein the upper cell may include a stack in which a hole transport layer, a perovskite light absorbing layer, an electron transport layer and a transparent electrode are sequentially stacked.

In a preferred embodiment of the present invention, a tandem perovskite solar cell may be cut in vertical direction on one side of the transparent electrode to divide the recombination layer and the upper cell into three parts.

In a preferred embodiment of the present invention, a tandem perovskite solar cell may be cut in a vertical direction on one side of a transparent electrode to divide part or all of the upper cell into three parts.

In a preferred embodiment of the present invention, a tandem perovskite solar cell may include a recombination layer and/or an upper cell, each having a central portion and both end portions with respect to a cut surface.

In a preferred embodiment of the present invention, the tandem perovskite solar cell may have a width of 1 to 40 μm.

In a preferred embodiment of the present invention, the tandem perovskite solar cell may satisfy Condition (1).

$$99.45 \% \leq \frac{\{ A - 2 ( B + C ) \}}{A} \times 100 \leq 99.95 \% \qquad ( 1 )$$

In the above Condition (1), A represents a length of the central portion, B represents a length of one end portion, and C represents a width of the cut surface.

In a preferred embodiment of the present invention, a stack of the tandem perovskite solar cell may further include a metal electrode formed on one surface of the transparent electrode central portion.

In a preferred embodiment of the present invention, a stack of the tandem perovskite solar cell may further include an intermediate layer between the perovskite light absorbing layer and the electron transport layer.

### Effects of the Invention

The tandem perovskite solar cell and the manufacturing method thereof according to the present invention cut off a shunt path so that charge can move toward a charge selective layer, thereby enabling manufacture of a perovskite solar cell having excellent performance.

In addition, the tandem perovskite solar cell of the present invention and a manufacturing method thereof have a simple and easy manufacturing process.

In addition, the tandem perovskite solar cell of the present invention and the manufacturing method thereof can reduce output loss by reducing the loss area.

### BRIEF DESCRIPTION OF THE DRAWINGS

FIG. 1 is a conceptual view for explaining a shunt path generated when depositing the transparent electrode on an electron transport layer in a manufacturing method of a conventional tandem perovskite solar cell.

FIG. 2 is a conceptual view illustrating the process of performing laser edge isolation after depositing a transparent electrode on an electron transport layer in the manufacturing method of tandem perovskite solar cells according to one embodiment of the present invention.

FIGS. 3 and 4 are cross-sectional views of a tandem perovskite solar cell according to an exemplary embodiment.

FIGS. 5 and 6 are cross-sectional views of a tandem perovskite solar cell according to another embodiment of the present invention.

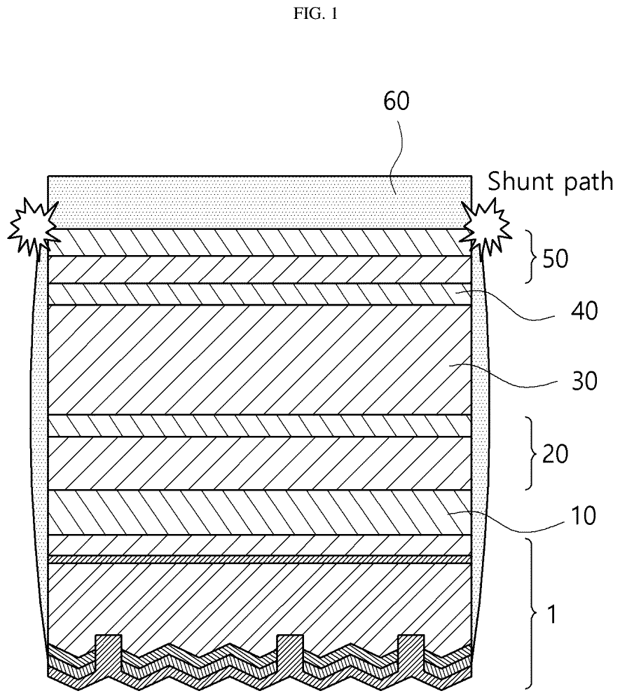

### DETAILED DESCRIPTION

Hereinafter, the present invention will be described in more detail.

When manufacturing the conventional perovskite solar cell, a bottom-up method is mainly used, but this method has disadvantages in that mass production is insufficient and non-deposition area occurs and the deposition time is long due to the use of a tray. To solve these problems, a top-down method should be introduced for high speed and full surface deposition. However, when the transparent electrode is deposited on the electron transport layer using the top-down method, since it is difficult to deposit only on the upper surface of the electron transport layer, the transparent electrode is deposited without directionality and also on the side surfaces of the perovskite solar cell, thereby forming a shunt path, which prevents it from performing a charge selective role, accelerates charge recombination, and ultimately causes heat generation in the perovskite solar cell.

Accordingly, the present invention provides a tandem perovskite solar cell having excellent performance and a manufacturing method thereof by introducing a laser edge isolation process after depositing a transparent electrode in a process of manufacturing a perovskite solar cell to cut off a shunt path so that charge can move toward a charge selective layer.

The manufacturing method of the perovskite solar cell of the present invention includes first step to fourth step.

First, in the first step of a manufacturing method of a perovskite solar cell according to the present invention, a stack including a hole transport layer, a perovskite light absorbing layer and an electron transport layer may be prepared. In this case, the stack may further include an intermediate layer between the perovskite light absorbing layer and the electron transport layer.

The hole transport layer (HTL or hole transporting layer) is a layer that transports holes generated in the perovskite light absorbing layer and blocks electrons from moving, and may include inorganic and/or organic hole transport material.

In this case, the inorganic hole transport material may include one or more selected from nickel oxide (NiOx), CuSCN, CuCrO₂, CuI, MoO and V₂O₅.

In addition, the organic hole transport material may include one or more selected from carbazole derivatives, polyarylalkane derivatives, phenylenediamine derivatives, arylamine derivatives, amino-substituted chalcone derivatives, styryl anthracene derivatives, fluorene derivatives, hydrazone derivatives, stilbene derivatives, silazane derivatives, aromatic tertiary amine compounds, styrylamine compounds, aromatic dimethylidine-based compounds, porphyrin-based compounds, phthalocyanine-based compounds, polythiophene derivatives, polypyrrole derivatives, polyparaphenylenevinylene derivatives, pentacene, coumarin 6, 3-(2-benzothiazolyl)-7-(diethylamino)coumarin), ZnPC(zinc phthalocyanine), CuPC(copper phthalocyanine), TiOPC(titanium oxide phthalocyanine), Spiro-MeOTAD(2,2′,7,7′-tetrakis(N,N-p-dimethoxyphenylamino)-9,9′-spirobifluorene), F16CuPC(copper(II) 1,2,3,4,8,9,10,11,15,16,17,18,22,23,24,25-hexadecafluoro-29H,31H-phthalocyanine), SubPc(boron subphthalocyanine chloride) and N3(cis-di(thiocyanato)-bis(2,2′-bipyridyl-4,4′-dicarboxylic acid)-ruthenium(II), P3HT(poly[3-hexylthiophene]), MDMO-PPV(poly[2-methoxy-5-(3′,7′-dimethyloctyloxyl)]-1,4-phenylene vinylene), MEH-PPV(poly[2-methoxy-5-(2″-ethylhexyloxy)-p-phenylene vinylene]), P30T(poly(3-octyl thiophene)), POT(poly(octyl thiophene)), P3DT(poly(3-decyl thiophene)), P3DDT(poly(3-dodecyl thiophene), PPV(poly(p-phenylene vinylene)), TFB(poly(9,9′-dioctylfluorene-co-N-(4-butylphenyl)diphenyl amine), Polyaniline, Spiro-MeOTAD([2,22′,7,77′-tetrkis (N,N-di-pmethoxyphenyl amine)-9,9,9′-spirobi fluorine]), PCPDTBT(Poly[2,1,3-benzothiadiazole-4,7-diyl[4,4-bis(2-ethylhexyl-4H-cyclopenta [2,1-b:3,4-b′]dithiophene-2,6-diyl]], Si-PCPDTBT(poly[(4,4′-bis(2-ethylhexyl)dithieno[3,2-b:2′,3′-d]silole)-2,6-diyl-alt-(2,1,3-benzothiadiazole)-4,7-diyl]), PBDTTPD(poly((4,8-diethylhexyloxyl), PFDTBT(poly[2,7-(9-(2-ethylhexyl)-9-hexyl-fluorene)-alt-5,5-(4′,7, -di-2-thienyl-2′,1′,3′-benzothiadiazole)]), PFO-DBT(poly[2,7-.9,9-(dioctyl-fluorene)-alt-5,5-(4′,7′-di-2-.thienyl-2′,1′,3′-benzothiadiazole)]), PSiFDTBT(poly[(2,7-dioctylsilafluorene)-2,7-diyl-alt-(4,7-bis(2-thienyl)-2,1,3-benzothiadiazole)-5,5′-diyl]), PCDTBT(Poly [[9-(1-octylnonyl)-9H-carbazole-2,7-diyl]-2,5-thiophenediyl-2,1,3-benzothiadiazole-4,7-diyl-2,5-thiophenediyl]), PFB(poly(9,9′-dioctylfluorene-co-bis(N,N′-(4,butylphenyl))bis(N,N′-phenyl-1,4-phenylene)diamine), F8BT(poly(9,9′-dioctylfluorene-cobenzothiadiazole), PEDOT (poly(3,4-ethylenedioxythiophene)), PEDOT:PSS poly(3,4-ethylenedioxythiophene) poly(styrenesulfonate), PTAA (poly(triarylamine)), 2-PACz, MeO-2PACz, Br-2PACz, Me-4PACz, MeO-4PACz and 6-PACz.

In addition, the formation method of the hole transport layer may include a coating method such as gravure coating, bar coating, printing coating, spraying, spin coating, dipping and die coating; and vacuum deposition.

In addition, the thickness of the hole transport layer is not particularly limited, but may be preferably in a range of 5 nm to 40 nm and more preferably in a range of 10 nm to 30 nm.

The perovskite light absorbing layer may include a perovskite material represented by Chemical Formula 1 below.

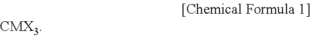

In Chemical Formula 1, C is a monovalent cation and may include an amine, ammonium, Group 1 metal, Group 2 metal, and/or other cations or cation-like compounds, preferably formamidinium (FA), methylammonium (MA), FAMA, CsFAMA, CsFA, or N(R)₄ (where R may be the same as or different from each other, and R is a linear alkyl group having 1 to 5 carbon atoms, a branched alkyl group having 3 to 5 carbon atoms, a phenyl group, an alkylphenyl group, an alkoxyphenyl group, or an alkylhalide).

In addition, in Chemical Formula 1, M is a divalent cation and may include one or two selected from among Fe, Co, Ni, Cu, Sn, Pb, Bi, Ge, Ti, Eu, and Zr.

In addition, in Chemical Formula 1, X is a monovalent anion and may include at least one of halide elements selected from among F, Cl, Br and I and/or Group 16 anions, and preferably, X may be IxBr₃₋ₓ(0≤x≤3).

In addition, in a preferred embodiment of Chemical Formula 1, the compound may be FAPbIₓBr₃₋ₓ(0≤x≤3), MAPbIₓBr₃₋ₓ(0≤x≤3), CSFAPbIₓBr₃₋ₓ(0≤x≤3), CSMAFAPbIₓBr₃₋ₓ (0≤x≤3), CH₃NH₃PbX₃ (X=Cl, Br, I, BrI₂, or Br₂I), CH₃NII₃SnX₃ (X=Cl, Br or I), CH(═NH)NH₃PbX₃ (X═Cl, Br, I, BrI₂, or Br₂I) or CH(═NH)NH₃SnX₃ (X═Cl, Br or I).

Meanwhile, the perovskite light absorbing layer may be a single layer formed of the same perovskite material or a multilayer structure in which multiple layers formed of different perovskite materials are stacked, and may include a hetero perovskite material having a pillar shape such as a columnar shape, plate shape, needle shape, wire shape, or rod shape inside the light absorbing layer formed of one kind of perovskite material other than the hetero perovskite.

In addition, the method for forming a perovskite light absorbing layer may be performed by using a deposition process and a solution process, wherein the deposition process may include any general deposition processes used in the art such as thermal evaporation, vacuum deposition, atomic layer deposition (ALD), chemical vapor deposition (CVD), physical vapor deposition (PVD), etc., and the solution process may include any general solution processes used in the art such as spin coating, slot die coating, blade coating, printing coating, gravure coating, and spray coating.

In addition, the thickness of the perovskite light absorbing layer is not particularly limited, but may be preferably in a range of 50 nm to 800 nm and more preferably in a range of 300 nm to 600 nm.

The intermediate layer may comprise lithium fluoride (LiF).

In addition, the method for forming the intermediate layer may be performed by using a deposition process and a solution process, wherein the deposition process may include any general deposition processes used in the art such as thermal evaporation, vacuum deposition, atomic layer deposition (ALD), chemical vapor deposition (CVD), physical vapor deposition (PVD), etc., and the solution process may include any general solution processes used in the art such as spin coating, slot die coating, blade coating, printing coating, gravure coating, and spray coating.

In addition, the thickness of the intermediate layer is not particularly limited, but preferably may have an average thickness of 0.5 to 3 nm and more preferably 0.5 to 1 nm.

The electron transport layer (ETL) is a layer that transports electrons generated in the perovskite light absorbing layer and blocks holes from moving.

The electron transport layer may include one or more selected from fullerene-based organic materials and inorganic materials. In this case, the fullerene-based organic material may include one or more selected from C₆₀ fullerene, C₇₀ fullerene, PC60BM, PC70BM, and ICBA, and the inorganic material may include one or more selected from tin oxide (SnOₓ), tin oxide (SnO₂), titanium dioxide (TiO₂), zinc oxide (ZnO), cerium oxide (CeO₂), barium stannate (BaSnO₃), niobium hydroxide (NbOH), and niobium pentoxide (Nb₂O).

In addition, the electron transport layer may further include an organic material, and the organic material may include one or more selected from non-fullerene derivatives other than fullerene series, naphthalene derivatives, conjugated polymer derivatives, NDI-based polymers, 2,2′-((2Z,2′Z)-((4,4,9,9-tetrakis(4-hexylphenyl)-4,9-dihydro-s-indaceno[1,2-b:5,6-b′]dithiophene-2,7-diyl)bis(methanylylidene))bis(5,6-difluoro-3-oxo-2,3-dihydro-1H-indene-2,1-diylidene))dimalononitrile (ITIC), poly(ethyleneimine) (PEI), poly(ethylenimine)-ethoxylated (PEIE), poly(3-hexylthiophene) (P3HT), tetrathiafulvalene (TTF), and bathocuproine (BCP).

In addition, the method for forming an electron transport layer may be performed by using a deposition process and a solution process, wherein the deposition process may include any general deposition processes used in the art such as thermal evaporation, vacuum deposition, atomic layer deposition (ALD), chemical vapor deposition (CVD), physical vapor deposition (PVD), etc., and the solution process may include any general solution processes used in the art such as spin coating, slot die coating, blade coating, printing coating, gravure coating, and spray coating.

In addition, the thickness of the electron transport layer is not particularly limited, but may be preferably in a range of 3 nm to 30 nm and more preferably in a range of 5 nm to 20 nm.

The second step of the manufacturing method of a perovskite solar cell according to the present invention may form a transparent electrode on the electron transport layer.

The transparent electrode may be formed through a deposition process. In this case, the deposition process may be performed by using a general deposition process used in the art and preferably, the deposition process may be performed by using a sputtering method.

In addition, the transparent electrode may be a transparent thin film formed by depositing indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO).

In addition, the thickness of the transparent electrode is not particularly limited, but may be preferably in a range of 50 nm to 200 nm and more preferably in a range of 50 nm to 80 nm.

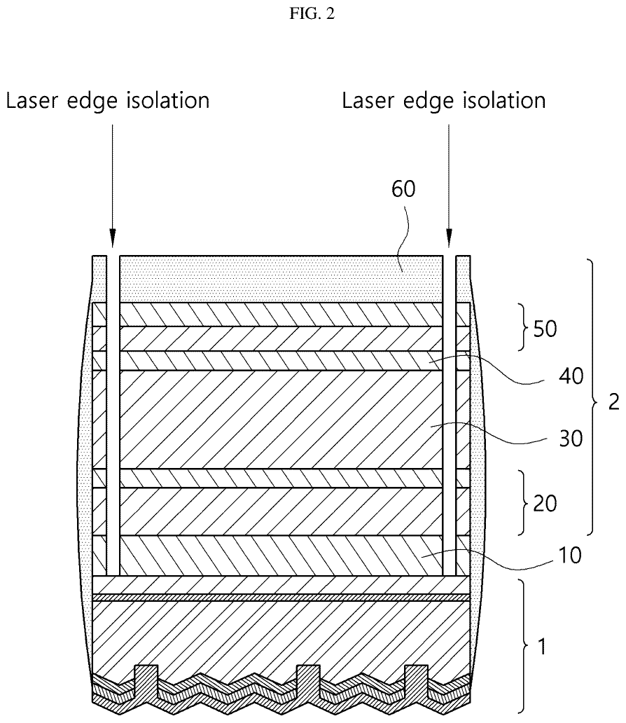

Referring to FIG. 2, in the third step of the manufacturing method of a perovskite solar cell according to the present invention, both ends of the transparent electrode 60 may be cut off in a vertical direction on one surface of the transparent electrode 60 through a laser edge isolation process.

The laser edge isolation process is a process of etching an edge portion of the film, thin film or layer using a laser and may be performed by using a pulsed laser as one example without any limitation.

Specifically, the laser edge isolation process may be performed using a pulsed laser under a picosecond condition.

In addition, the laser edge isolation process may be performed using a pulsed laser under conditions of a laser wavelength of 300 to 400 nm, preferably 320 to 380 nm, and more preferably 350 to 370 nm. If the laser wavelength is 532 nm, the energy density of the laser beam decreases, and since the energy penetrates into the material surface depth and is converted into heat, there are problems in that the area of the heat effect region becomes large, and precision is lowered compared to an energy wavelength of 355 nm. In this case, it is impossible to satisfy the line width to be processed, thereby causing an area loss, and in an IR laser having a laser wavelength of 1064 nm, the energy deeply penetrates into the inside of the substance so that the heat effect region becomes wide and shock wave phenomena exist, which makes it difficult to perform precise processing.

In addition, the laser edge isolation process may be performed using a pulsed laser under conditions of pulse duration of 5 to 15 Ps, preferably 7 to 13 Ps, and more preferably 9 to 11 Ps, and there may be an economic problem if the pulse duration is less than 5 Ps, while there may be a problem in precision processing if it exceeds 15 Ps.

In addition, the laser edge isolation process may be performed using a pulsed laser under conditions of power from 0.1 to 1.0 W, preferably from 0.2 to 0.8 W, and more preferably from 0.3 to 0.6 W.

In addition, the laser edge isolation process may be performed using a pulsed laser at a scan speed of 500 to 1,500 mm/s, preferably 800 to 1,200 mm/s, and more preferably 900 to 1,100 mm/s, wherein if the scan speed is less than 500 mm/s, an unnecessary laser depth may increase and a processing line width may become wide, and if it exceeds 1,500 mm/s, a spot distance becomes wide so that a laser line may not be formed as a solid line but in a dotted line form, thereby failing to achieve the desired isolation.

In addition, the laser edge isolation process may be performed using a pulsed laser at a repetition rate of 300 to 700 kHz, preferably 400 to 600 kHz, and more preferably 450 to 550 kHz, and if the repetition rate is less than 300 kHz, the spot distance becomes wide so that the laser line may not be formed as a solid line but in a dotted line form, which may cause a problem in that the desired isolation cannot be achieved, and if it exceeds 700 kHz, there may be a problem in that the desired isolation cannot be achieved.

In addition, the laser edge isolation process may be performed under conditions of a scanner z-axis of 5.0 to 15.0 mm, preferably 7.0 to 13.0 mm, and more preferably 10.0 to 12.0 mm using a pulsed laser, and if the scanner z-axis is less than 5.0 mm, there may be problems in that precision processing becomes difficult and manufactured perovskite solar cells are damaged, and if it exceeds 15.0 mm, there may be problems in that efficient processing is not made.

In addition, the laser edge isolation process may be performed using a pulsed laser under conditions of spot distance of 0.5 to 5 μm, preferably 1.0 to 3 μm, and more preferably 1.5 to 2.5 μm, wherein if the spot distance is less than 0.5 μm, there may be problems in that the depth of laser isolation increases and the width of processing line becomes larger than necessary, and if it exceeds 5 μm, there may be problems in that leakage current occurs due to insufficient insulation.

The fourth step of the manufacturing method of a perovskite solar cell according to the present invention may form a metal electrode on the transparent electrode having undergone laser edge isolation.

The metal electrode may be formed by patterning a metal material on the transparent electrode, and specifically, the patterning process includes deposition, lithography, and etching, in which a thin film of the metal material is deposited on one surface of the substrate, a pattern is printed through exposure, and unnecessary portions are removed to form the metal electrode on the transparent electrode. In addition, the patterning process may be performed using a screen printing method with a metal paste including the metal material. More specifically, the metal electrode may include a plurality of bus bar electrodes arranged horizontally and a plurality of finger electrodes arranged vertically from the bus bar electrodes.

In addition, the metal material may include one or more selected from the group consisting of Pt, Au, Ni, Cu, Ag, In, Ru, Pd, Rh, Ir, Os, C and a conductive polymer.

In addition, the thickness of the metal electrode is not particularly limited, but may be in a range of 50 nm to 15 μm.

Meanwhile, the manufacturing method of a tandem perovskite solar cell of the present invention includes a first step to fourth step.

In the first step of a manufacturing method of a tandem perovskite solar cell according to the present invention, a stack including a lower cell, a recombination layer, a hole transport layer, a perovskite light absorbing layer and an electron transport layer may be prepared in sequence. In this case, an intermediate layer may be further included between the perovskite light absorbing layer and the electron transport layer, and each of the hole transport layer, the perovskite light absorbing layer, the intermediate layer and the electron transport layer is as described above.

The lower cell may be a polycrystalline silicon solar cell, a crystalline silicon solar cell, a perovskite solar cell, a gallium arsenide (GaAs) solar cell, a cadmium telluride (CdTe) solar cell, a CuInGaSe (CIGS) solar cell, a Cu2ZnSnS4 (CZTS) solar cell, an organic solar cell, a dye-sensitized solar cell, or a group III-V compound solar cell.

In addition, the thickness of the lower cell is not particularly limited, but may be preferably in a range of 140 to 250 μm and more preferably in a range of 160 to 200 μm.

In addition, when a silicon solar cell doped with an n- or p-type impurity is used as the lower cell, the silicon solar cell may be treated with hydrofluoric acid to remove the SiOx oxide film and then washed with ultrapure water to remove residual hydrofluoric acid.

The recombination layer is a layer that induces the recombination of electrons and holes generated in the lower cell and the perovskite light absorbing layer, and may be a transparent thin film formed by depositing indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO).

In addition, as an example of forming the recombination layer, a recombination layer may be formed on the lower cell through a sputtering process.

In addition, the thickness of the recombination layer is not particularly limited, but may be preferably in a range of 5 nm to 50 nm and more preferably in a range of 10 nm to 25 nm.

The second step of the manufacturing method of a tandem perovskite solar cell according to the present invention may form a transparent electrode on the electron transport layer. In this case, the transparent electrode is as described above.

In the third step of the manufacturing method of a tandem perovskite solar cell according to the present invention, both ends of the transparent electrode may be cut in a vertical direction on one surface of the transparent electrode through a laser edge isolation process. Herein, the laser edge isolation process is as described above. In addition, the recombination layer, the hole transport layer, the perovskite light absorbing layer and the electron transport layer may be cut by using a laser edge isolation process, and the lower cell may not cut. In addition, through the laser edge isolation process, the hole transport layer, the perovskite light absorbing layer and the electron transport layer may be cut, but the recombination layer and the lower cell may not be cut.

In addition, through a laser edge isolation process, part of the hole transport layer, the perovskite light absorbing layer and the electron transport layer may be cut off, while other parts of the hole transport layer, the recombination layer and the lower cell are not cut off.

The fourth step of the manufacturing method of a tandem perovskite solar cell according to the present invention may form a metal electrode on the transparent electrode. Herein, the metal electrode is as described above.

In addition, the perovskite solar cell of the present invention may be manufactured by the manufacturing method of a perovskite solar cell described above.

Meanwhile, the tandem perovskite solar cell of the present invention may be manufactured by the manufacturing method of a tandem perovskite solar cell described above.

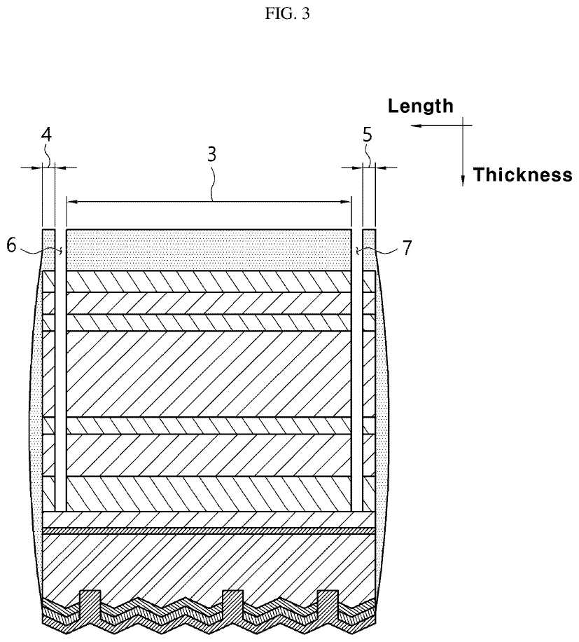

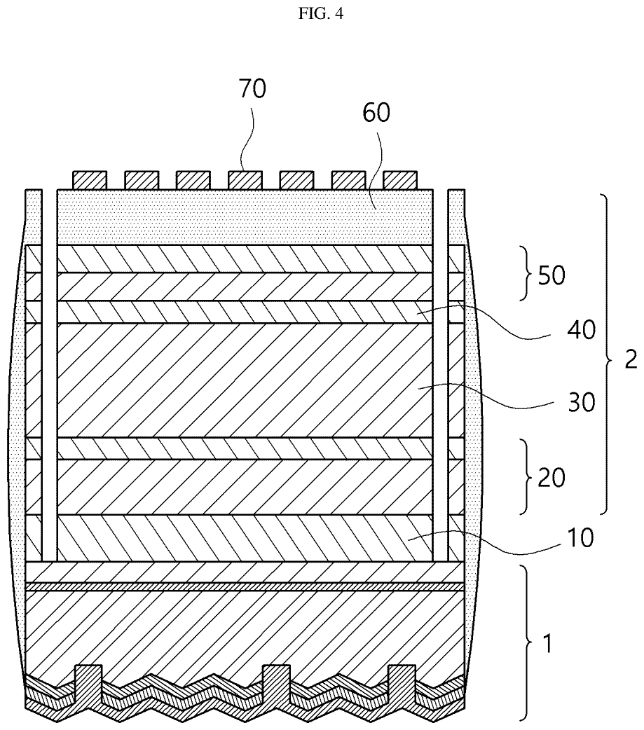

In addition, referring to FIGS. 3 and 4, the tandem perovskite solar cell of the present invention has a structure in which a lower cell 1, a recombination layer 10, and an upper cell 2 are sequentially stacked, wherein the upper cell 2 may include a stack including a hole transport layer 20, a perovskite light absorbing layer 30, an electron transport layer 50, and a transparent electrode 60. In this case, an intermediate layer 40 may be further included between the perovskite light absorbing layer 30 and the electron transport layer 50, and the lower cell 1, recombination layer 10, hole transport layer 20, perovskite light absorbing layer 30, intermediate layer 40, electron transport layer 50, and transparent electrode 60 are as described above, respectively.

Specifically, the tandem perovskite solar cell of the present invention is cut in a vertical direction to one surface of the transparent electrode 60, so that the recombination layer 10 and the upper cell 2 may be divided into three parts, and the recombination layer 10 and the upper cell 2 may include a central portion 3 and both end portions 4 and 5 based on the cut surfaces 6 and 7.

In this case, the cut surfaces 6 and 7 may have a width of 1 to 40 μm, preferably 30 to 40 μm, and if the width of the cut surface exceeds 40 μm, there is a problem that performance of the solar cell deteriorates.

The tandem perovskite solar cell of the present invention may satisfy Condition (1).

$$99.45 \% \leq \frac{\{ A - 2 ( B + C ) \}}{A} \times 100 \leq 99.95 \% , \qquad ( 1 )$$

preferably

$$99.65 \% \leq \frac{\{ A - 2 ( B + C ) \}}{A} \times 100 \leq 99.9 \% ,$$

more preferably

$$99.8 \% \leq \frac{\{ A - 2 ( B + C ) \}}{A} \times 100 \leq 99.85 \%$$

In the above Condition (1), A represents the length of the central portion 3, B represents the length of one end portion 4 or 5, and C represents the width of the cut surface 6 or 7.

In Condition (1), if

$$\frac{\{ A - 2 ( B + C ) \}}{A} \times 100$$

is less than 99.45%, there may be a problem in that performance of the solar cell decreases and a shunt path occurs, and if it exceeds 99.95%, there may be problems in that processability deteriorates and process reliability decreases.

In addition, the tandem perovskite solar cell of the present invention may further include a metal electrode 70 formed on one surface of the central portion 3 of the transparent electrode 60, and the metal electrode 70 is as described above.

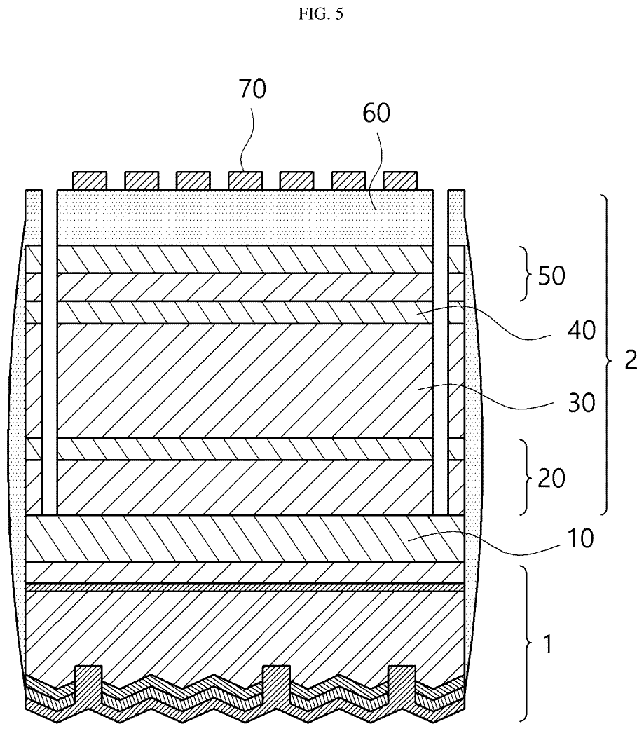

In addition, referring to FIG. 5, the tandem perovskite solar cell of the present invention is cut in a vertical direction to one surface of the transparent electrode 60 so that the recombination layer 10 is not divided and only the upper cell 2 may be divided into three parts, and the upper cell 2 may include a central portion 3 and both end portions 4 and 5 based on the cut surfaces 6 and 7.

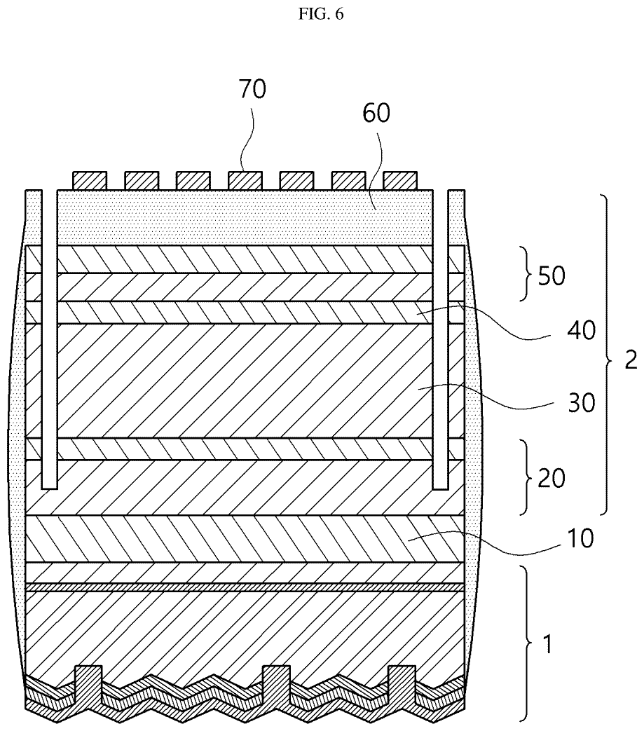

In addition, referring to FIG. 6, the tandem perovskite solar cell of the present invention is cut in a vertical direction to one surface of the transparent electrode 60, so that the recombination layer 10 and a part of the upper cell 2 are not divided, only another part of the upper cell 2 may be divided into three parts, and the other part of the cut upper cell 2 may include a central portion 3 and both end portions 4 and 5 based on the cut surfaces 6 and 7.

In this case, the cutting surfaces 6 and 7 may have a width of 1 to 40 μm, preferably 30 to 40 μm, and satisfy Condition (1).

$$99.45 \% \leq \frac{\{ A - 2 ( B + C ) \}}{A} \times 100 \leq 99.95 \% , \qquad ( 1 )$$

preferably

$$99.65 \% \leq \frac{\{ A - 2 ( B + C ) \}}{A} \times 100 \leq 99.9 \% ,$$

more preferably

$$99.8 \% \leq \frac{\{ A - 2 ( B + C ) \}}{A} \times 100 \leq 99.85 \%$$

In the above Condition (1), A represents the length of the central portion 3, B represents the length of one end portion 4 or 5, and C represents the width of the cut surface 6 or 7.

Hereinafter, the present invention will be described in more detail with reference to examples, and yet, it should be understood that these examples are merely for illustrative purposes and do not limit the scope of the present invention.

### Embodiment 1: Fabrication of Tandem Silicon/Perovskite Heterojunction Solar Cells

(1) A silicon solar cell (thickness: 180 m) doped with an n-type or p-type impurity was prepared and was treated with hydrofluoric acid to remove the SiOx oxide film, and then residual hydrofluoric acid was removed using ultrapure water.

(2) A recombination layer (ITO) having a thickness of 10 nm was formed on the silicon solar cell from which the oxide film had been removed by using a sputtering process.

(3) A nickel oxide (NiOx) layer having a thickness of 15 nm was deposited on the recombination layer by using a sputtering method, and then Me-4PACz having a thickness of 3 nm was coated on the nickel oxide layer by spin coating to form a hole transport layer.

(4) A yellow light absorbing layer solution formed by dissolving dimethylformamide (DMF) and dimethyl sulfoxide (DMSO) was coated on the hole transport layer using a blade coating method, and heat treated at 150° C. for 20 minutes to form a perovskite light absorbing layer having a perovskite crystal structure with a thickness of 600 nm (CSFAPbIₓBr₃₋ₓ (0≤x≤3)).

(5) A thickness of 1 nm of lithium fluoride (LiF) was deposited on the perovskite light absorbing layer through a thermal evaporation process to form an intermediate layer on the perovskite light absorbing layer.

(6) Fullerene C₆₀ was deposited on the perovskite light absorbing layer by a thermal evaporation process, and then tin oxide (SnOₓ) was deposited thereon by an atomic layer deposition (ALD) process to form an electron transport layer having an average thickness of 6 nm.

(7) A transparent electrode (ITO) having a thickness of 50 nm was formed on the electron transport layer through sputtering.

(8) The transparent electrode was cut at both ends thereof in a vertical direction of one surface of the transparent electrode through a laser edge isolation process. In this case, the laser edge isolation process was performed using a pulsed laser under conditions of picoseconds, a laser wavelength of 355 nm, a pulse duration of 10 ps, power of 0.4 W, scan speed of 1,000 mm/s, repetition rate of 500 kHz, scanner z-axis of 11.0 mm and spot distance of 2 μm. In addition, it was confirmed that an area loss due to the laser edge isolation process was very small as 0.4% with respect to the total area. In addition, the recombination layer, the hole transport layer, the perovskite light absorbing layer, the intermediate layer, the electron transport layer, and the transparent electrode were divided into three parts by cutting through the laser edge isolation process, wherein the recombination layer, the hole transport layer, the perovskite light absorbing layer, the intermediate layer, the electron transport layer and the transparent electrode included a central portion and both end portions with respect to a cut surface. In addition, the cut surfaces had a width of 35 μm, and the calculation value of the

$$\frac{\{ A - 2 ( B + C ) \}}{A} \times 100 ,$$

which is Condition (1), was confirmed to be 99.83% (A represents a length of the central portion, B represents a length of one end portion, and C represents a width of the cut surface).

(9) The metal electrode was formed by depositing silver (Ag) on the upper portion of the transparent electrode using a screen printing process at a pressure of 65 N to a thickness of 15 um, thereby manufacturing a tandem silicon/perovskite heterojunction solar cell having a structure in which the silicon solar cell, recombination layer, hole transport layer, perovskite light absorbing layer, intermediate layer, electron transport layer, transparent electrode and metal electrode are sequentially stacked.

### Comparative Example 1: Fabrication of a Tandem Silicon/Perovskite Heterojunction Solar Cell

(1) A silicon solar cell (thickness: 180 m) doped with an n-type or p-type impurity was prepared and was treated with hydrofluoric acid to remove the SiOx oxide film, and then residual hydrofluoric acid was removed using ultrapure water.

(2) A recombination layer (ITO) having a thickness of 10 nm was formed on the silicon solar cell from which the oxide film had been removed by using a sputtering process.

(3) A nickel oxide (NiOx) layer having a thickness of 15 nm was deposited on the recombination layer by using a sputtering method, and then Me-4PACz having a thickness of 3 nm was coated on the nickel oxide layer by spin coating to form a hole transport layer.

(4) A yellow light absorbing layer solution formed by dissolving dimethylformamide (DMF) and dimethyl sulfoxide (DMSO) was coated on the hole transport layer using a blade coating method, and heat treated at 150° C. for 20 minutes to form a perovskite light absorbing layer having a perovskite crystal structure with a thickness of 600 nm (CSFAPbIₓBr₃-x (0≤x≤3)).

(5) A thickness of 1 nm of lithium fluoride (LiF) was deposited on the perovskite light absorbing layer through a thermal evaporation process to form an intermediate layer on the perovskite light absorbing layer.

(6) Fullerene C₆₀ was deposited on the perovskite light absorbing layer by a thermal evaporation process, and then tin oxide (SnOₓ) was deposited thereon by an atomic layer deposition (ALD) process to form an electron transport layer having an average thickness of 6 nm.

(7) A transparent electrode (ITO) having a thickness of 50 nm was formed on the electron transport layer through sputtering.

(8) The metal electrode was formed by depositing silver (Ag) on the transparent electrode to a thickness of 15 μm at a pressure of 65 N through screen printing, thereby manufacturing a tandem silicon/perovskite heterojunction solar cell in which the silicon solar cell, recombination layer, hole transport layer, perovskite light absorbing layer, intermediate layer, electron transport layer, transparent electrode and metal electrode are sequentially stacked.

### Experimental Example 1: Measurement of the Performance of a Solar Cell

The efficiency of each tandem silicon/perovskite heterojunction solar cell fabricated in Embodiment 1 and Comparative Example 1 was measured using a solar simulator and a JV Keithley instrument with an initial JV curve as shown in Table 1.

### Experimental Example 2: Measurement of Reverse Voltage of a Solar Cell

The reverse voltage was measured using a source meter in the dark state and under illumination of a solar simulator for each of the tandem silicon/perovskite heterojunction solar cells prepared in Embodiment 1 and Comparative Example 1 after applying leakage current evaluation, and the result is shown in Table 2 below.

TABLE 1

| | | | Short- | | | | | |
|---|---|---|---|---|---|---|---|---|
| | | | circuit | | | | | |
| | | Open | current | | Power | Series | Parallel | |
| | | circuit | density | Fill | conversion | resistance | resistance | |
| | | voltage | (Jsc, | factor | efficiencies | (Rₛ, | (Rₛₕ, | MPPT |
| Classification | Scan | (Voc, V) | mA/cm²) | (FF) | (%) | Ω*cm²) | Ω*cm²) | (%) |
| Embodiment 1 | R | 1.815 | 18.56 | 76.22 | 25.68 | 8.95 | 89,008 | 24.27 |
| | F | 1.788 | 18.55 | 60.68 | 20.12 | 11.42 | 5,611 | 24.27 |
| Comparative | R | 1.798 | 18.43 | 73.07 | 24.22 | 9.87 | 24,494 | 23.04 |
| Example 1 | F | 1.776 | 18.46 | 61.44 | 20.14 | 12.55 | 9,824 | 23.04 |

TABLE 2

| Classification | Reverse voltage@−15 V(A) |
|---|---|
| Embodiment 1 | 0.71 |
| Comparative Example 1 | 1.96 |

As can be seen in Table 1, the tandem silicon/perovskite heterojunction solar cell manufactured in Embodiment 1 had a higher power conversion efficiency and better maximum power point tracking (MPPT) than the tandem silicon/perovskite heterojunction solar cell manufactured in Comparative Example 1.

In addition, as shown in Table 2, the tandem silicon/perovskite heterojunction solar cell manufactured in Comparative Example 1 was measured to be 1.96 A at a reverse voltage of −15 V, and the tandem silicon/perovskite heterojunction solar cell manufactured in Embodiment 1 was measured to be 0.71 A, thereby confirming that, by performing a laser edge isolation process, the current at a reverse voltage of −15 V is reduced from 1.96 A to 0.71 A.

The above description has been made with reference to specific embodiments of the present invention. However, it should be noted that those skilled in the art may make various modifications and changes without departing from the spirit and scope of the invention as defined by the appended claims.

1. A manufacturing method of a perovskite solar cell, the method comprising:
a first step of preparing a stack in which a hole transport layer, a perovskite light absorbing layer and an electron transport layer are sequentially stacked;
a second step of forming a transparent electrode on the electron transport layer;
a third step of cutting both ends of the transparent electrode in a vertical direction to one surface of the transparent electrode through a laser edge isolation process; and
a fourth step of forming a metal electrode on the transparent electrode.

2. The manufacturing method of a perovskite solar cell of claim 1, wherein the stack further comprises an intermediate layer between the perovskite light absorbing layer and the electron transport layer.

3. The manufacturing method of a perovskite solar cell of claim 1, wherein the laser edge isolation process is performed using a pulsed laser under conditions of a laser wavelength of 300 to 400 nm and a pulse duration of 5 to 15 ps.

4. The manufacturing method of a perovskite solar cell of claim 3, wherein the laser edge isolation process is performed under conditions of a power of 0.1 to 1.0 W, a scan speed of 500 to 1,500 mm/s, a repetition rate of 300 to 700 kHz, a scanner z-axis of 5.0 to 15.0 mm, and a spot distance of 0.5 to 5 μm.

5. The manufacturing method of a perovskite solar cell of claim 1, wherein the transparent electrode is a transparent thin film formed by depositing indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO).

6. The manufacturing method of a perovskite solar cell of claim 1, wherein the perovskite light absorbing layer comprises a perovskite material represented by Chemical Formula 1 below: 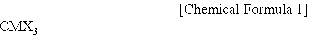
where, in Chemical Formula 1, C is a monovalent cation, M is a divalent cation, and X is a monovalent anion.

7. A manufacturing method of a tandem perovskite solar cell comprising:
a first step of preparing a stack in which a lower cell, a recombination layer, a hole transport layer, a perovskite light absorbing layer and an electron transport layer are sequentially stacked;
a second step of forming a transparent electrode on the electron transport layer;
a third step of cutting both ends of the transparent electrode in a vertical direction to one surface of the transparent electrode through a laser edge isolation process; and
a fourth step of forming a metal electrode on the transparent electrode.

8. The manufacturing method of a tandem perovskite solar cell of claim 7, wherein the recombination layer, the hole transport layer, the perovskite light absorbing layer and the electron transport layer are cut by using a laser edge isolation process, and the lower cell is not cut.

9. The manufacturing method of a tandem perovskite solar cell of claim 8, wherein the lower cell in the first step is a polycrystalline silicon solar cell, a crystalline silicon solar cell, a perovskite solar cell, a gallium arsenide (GaAs) solar cell, a cadmium telluride (CdTe) solar cell, a CuInGaSe (CIGS) solar cell, a Cu2ZnSnS4 (CZTS) solar cell, an organic solar cell, a dye-sensitized solar cell, or a group III-V compound solar cell.

10. A tandem perovskite solar cell in which a lower cell, a recombination layer, and an upper cell are sequentially stacked,
wherein the upper cell comprises a stack in which a hole transport layer, a perovskite light absorbing layer, an electron transport layer, and a transparent electrode are sequentially stacked,
wherein, when cut in a vertical direction to one surface of the transparent electrode, the recombination layer and the upper cell are divided into three parts, and
wherein the recombination layer and the upper cell consist of a central portion and both end portions with respect to a cut surface.

11. The tandem perovskite solar cell of claim 10, wherein the recombination layer and each of the upper cells have a cut surface having a width of 1 to 40 μm and satisfy Condition (1):
$$99.45 \% \leq \frac{\{ A - 2 ( B + C ) \}}{A} \times 100 \leq 99.95 \% \qquad ( 1 )$$
where A represents a length of the central portion, B represents a length of one end portion, and C represents a width of the cut surface in Condition (1).

12. The tandem perovskite solar cell of claim 10, wherein the stack further comprises a metal electrode formed on one surface of the transparent electrode central portion.

13. The tandem perovskite solar cell of claim 10, wherein the stack further comprises an intermediate layer between the perovskite light absorbing layer and the electron transport layer.

14. A tandem perovskite solar cell in which a lower cell, a recombination layer, and an upper cell are sequentially stacked,
wherein the upper cell comprises a stack in which a hole transport layer, a perovskite light absorbing layer, an electron transport layer, and a transparent electrode are sequentially stacked,
wherein, when cut in a vertical direction to one surface of the transparent electrode, all or part of the upper cell is divided into three parts, and
wherein the upper cell consists of a central portion and both end portions with respect to a cut surface.

15. The tandem perovskite solar cell of claim 14, wherein the upper cell has a cut surface having a width of 1 to 40 μm and satisfies Condition (1):
$$99.45 \% \leq \frac{\{ A - 2 ( B + C ) \}}{A} \times 100 \leq 99.95 \% \qquad ( 1 )$$
where A represents a length of the central portion, B represents a length of one end portion, and C represents a width of the cut surface in Condition (1).

16. The tandem perovskite solar cell of claim 14, wherein the stack further comprises a metal electrode formed on one surface of the transparent electrode central portion.

17. The tandem perovskite solar cell of claim 14, wherein the stack further comprises an intermediate layer between the perovskite light absorbing layer and the electron transport layer.
